(19) United States
(12) Patent Application Publication
(10) Pub. No.: US 2014/0118983 A1
(43) Pub. Date: May 1, 2014

(54) ASSEMBLING STRUCTURE OF INVERTER AND GROUND WIRE

(71) Applicant: DELTA ELECTRONICS, INC., Taoyuan Hsien (TW)

(72) Inventors: Sheng-Hua Li, Taoyuan Hsien (TW); Po-Hung Chen, Taoyuan Hsien (TW)

(73) Assignee: DELTA ELECTRONICS, INC., Taoyuan Hsien (TW)

(21) Appl. No.: 13/789,390

(22) Filed: Mar. 7, 2013

(30) Foreign Application Priority Data
Oct. 25, 2012 (TW) 101220558

(51) Int. Cl. H05K 7/12

(52) U.S. Cl. CPC H05K 7/12
USPC 361/807

(57) ABSTRACT

An assembling structure includes a ground wire, an inverter, a first fixing element, and a clamping device. The inverter includes a casing. The clamping device is disposed on the casing. The clamping device includes a first end, a second end, and a pressing part between the first end and the second end. The second end of the clamping device is previously fixed on the casing. After the ground wire is transferred through an entrance between the first end of the clamping device and the casing, the ground wire is clamped between the pressing part and the casing. Afterwards, by using the fixing element, the first end of the clamping device is fixed on the casing, the ground wire is fixed on the casing by the pressing part of the clamping device, and the inverter is fixed on the rack simultaneously.

### FIELD OF THE INVENTION

The present invention relates to an assembling structure, and more particularly to an assembling structure of an inverter and a ground wire.

### BACKGROUND OF THE INVENTION

Fossil fuels such as petroleum and coal are widely used in automobiles or power plants for generating motive force or electrical power. As known, burning fossil fuels produces waste gases and high temperature. The waste gases may pollute the air. In addition, carbon dioxide is considered to be a major cause of the enhanced greenhouse effect. It is estimated that the world's oils supply would be depleted in the next several decades. The oil depletion may lead to global economic crisis.

Consequently, there are growing demands on clean and renewable energy. The common renewable energy includes for example solar energy, wind power, tide energy, terrestrial heat, biomass energy, and the like. Among various renewable energy sources, solar energy is expected to replace fossil fuel as a new energy source because it provides clean energy without depletion. As a consequence, the solar energy is gradually adopted for establishing a distributed power supply system.

Generally, a solar power supply system comprises at least one solar panel, at least one inverter, and a ground system. The solar panel is used for receiving solar energy. By the inverter (e.g. a micro inverter), the solar energy is converted into electric energy, which is provided to a load or an energy storage device. The ground system is for example a ground wire. The ground system is connected with the inverter and the ground. The leakage current or the static electricity from the inverter is transferred to the ground through the ground system, so that the electric safety of the inverter can be maintained.

Conventionally, the inverter is fixed on a first position by a fixing element (e.g. a screw) and the ground wire is fixed on a second position by another fixing element (e.g. an additional screw). Since the two manual fixing steps are required to position the inverter and the ground wire, the conventional method of fixing the inverter and the ground wire is time-consuming and labor-intensive. In a case that the solar power supply system comprises more inverters, more fixing steps are required to position the inverters and the ground wires. Under this circumstance, the drawbacks become more obvious.

Therefore, there is a need of providing an improved assembling structure of an inverter and a ground wire in order to obviate the above drawbacks.

### SUMMARY OF THE INVENTION

The present invention provides an assembling structure of an inverter and a ground wire. The assembling structure comprises a clamping device. A second end of the clamping device is previously fixed on a casing of the inverter, so that clamping device has the function of a resilient sheet. The ground wire is firstly clamped between the clamping device and the casing. Then, by manually tightening a first fixing element into a first opening of the clamping device and a first perforation of the casing, the ground wire and the inverter are simultaneously fixed. Consequently, it is not necessary to manually perform two fixing steps to position the ground wire and the inverter. In other words, the method of fixing the ground wire and the inverter is time-saving and labor-saving.

In accordance with an aspect of the present invention, there is provided an assembling structure. The assembling structure includes a ground wire, an inverter, a first fixing element, and a clamping device. The inverter includes a casing. The casing has a first perforation. The clamping device is disposed on the casing. The clamping device includes a first end, a second end, and a pressing part between the first end and the second end. The second end of the clamping device is previously fixed on the casing. The first end of the clamping device has a first opening. After the ground wire is transferred through an entrance between the first end of the clamping device and the casing, the ground wire is clamped between the pressing part and the casing. After the first fixing element is tightened into the first opening and the first perforation, the first end of the clamping device is fixed on the casing, the ground wire is fixed on the casing by the pressing part of the clamping device, and the inverter is fixed on a rack simultaneously.

The above contents of the present invention will become more readily apparent to those ordinarily skilled in the art after reviewing the following detailed description and accompanying drawings, in which:

### BRIEF DESCRIPTION OF THE DRAWINGS

FIG. 1 is a schematic cross-sectional view illustrating an assembling structure fixed on a rack according to an embodiment of the present invention;

FIG. 2 is a schematic perspective view illustrating a portion of the assembling structure of FIG. 1;

FIG. 3 is a schematic enlarged perspective view illustrating the clamping device as shown in FIG. 2;

FIG. 4 is a schematic cross-sectional view illustrating an assembling structure fixed on a rack according to another embodiment of the present invention;

FIG. 5 is a schematic perspective view illustrating a portion of the assembling structure of FIG. 4; and

FIG. 6 is a schematic enlarged perspective view illustrating the clamping device as shown in FIG. 5.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

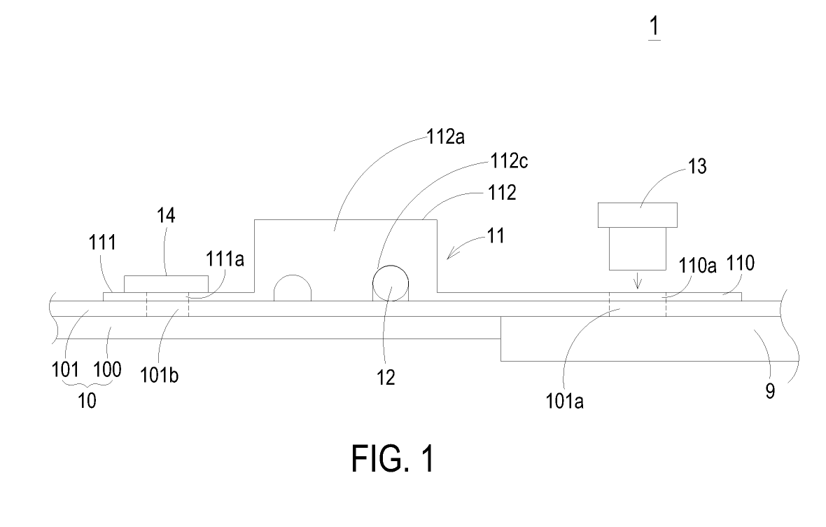

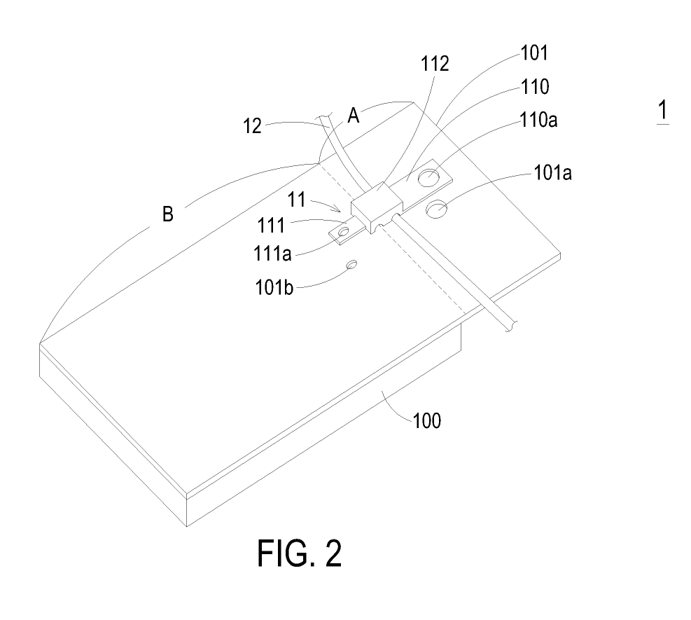

FIG. 1 is a schematic cross-sectional view illustrating an assembling structure fixed on a rack according to an embodiment of the present invention. FIG. 2 is a schematic perspective view illustrating a portion of the assembling structure of FIG. 1. As shown in FIGS. 1 and 2, the assembling structure 1 is fixed on a rack 9. The assembling structure 1 comprises an inverter 10, a clamping device 11, a ground wire 12, and a first fixing element 13. The inverter 10 is applied to a solar power supply system for example. The inverter 10 may be disposed on a backside of a solar panel. An example of the inverter 10 includes but is not limited to a micro inverter. The inverter 10 comprises a main body 100 and a casing 101. At least one circuit board (not shown) is disposed within the main body 100 for providing the main functions of the inverter 10. The main body 100 is covered by the casing 101. The main body 100 and the casing 101 are combined together. In addition, the casing 101 has a first perforation 101a.

In an embodiment, the casing 101 is longer than the main body 100. The casing 101 comprises a first part A and a second part B. The first part A is protruded outside the main body 100. The second part B is disposed over the main body 100. The first perforation 101a is located at the first part A of the casing 101.

The clamping device 11 is disposed on the casing 101. In addition, the clamping device 11 is made of a metallic material. In this embodiment, the clamping device 11 comprises a first end 110, a second end 111, and a pressing part 112. The pressing part 112 is arranged between the first end 110 and the second end 111. The second end 111 of the clamping device 11 is previously fixed on the second part B of the casing 101. For example, the second end 111 of the clamping device 11 may be previously fixed on the second part B of the casing 101 by a machining process in a factory. The first end 110 of the clamping device 11 is fixed on the first part A of the casing 101. Since the second end 111 of the clamping device 11 is previously fixed on the second part B of the casing 101, the first end 110 of the clamping device 11 is resilient and flexible. In response to an external force, the first end 110 of the clamping device 11 may be moved upwardly or downwardly and separated from the casing 101. In a case that the first end 110 of the clamping device 11 is moved upwardly relative to the casing 101, the ground wire 12 may be introduced into a region between the pressing part 112 and the casing 101 through an entrance between the first end 110 and the casing 101. Moreover, the first end 110 of the clamping device 11 further comprises a first opening 110a corresponding to the first perforation 101a. After the ground wire 12 is clamped between the pressing part 112 and the casing 101, the ground wire 12 is fixed on the casing 101 by the pressing part 112 of the clamping device 11.

An example of the first fixing element 13 includes but is not limited to a screw. By tightening the first fixing element 13 into the first opening 110a of the clamping device 11, the first perforation 101a of the casing 101 and a corresponding hole (not shown) of the rack 9, the first end 110 of the clamping device 11 is fixed on the casing 101. Correspondingly, the ground wire 12 is fixed on the casing 101 by the pressing part 112 of the clamping device 11, and the inverter 10 is fixed on the rack 9. Therefore, the inverter 10 and the ground wire 12 can be assembled together and fixed on the rack 9 by using the first fixing element 13 at the same fixing step.

The ground wire 12 is connected with the ground (not shown). Moreover, since the ground wire 12 is fixed on the casing 101 by the pressing part 112 of the clamping device 11, the leakage current or the static electricity from the inverter 10 can be transferred to the ground through the ground wire 12, so that the electric safety of the inverter 10 can be maintained. In some embodiments, the ground wire 12 complies with a European standard or a USA standard.

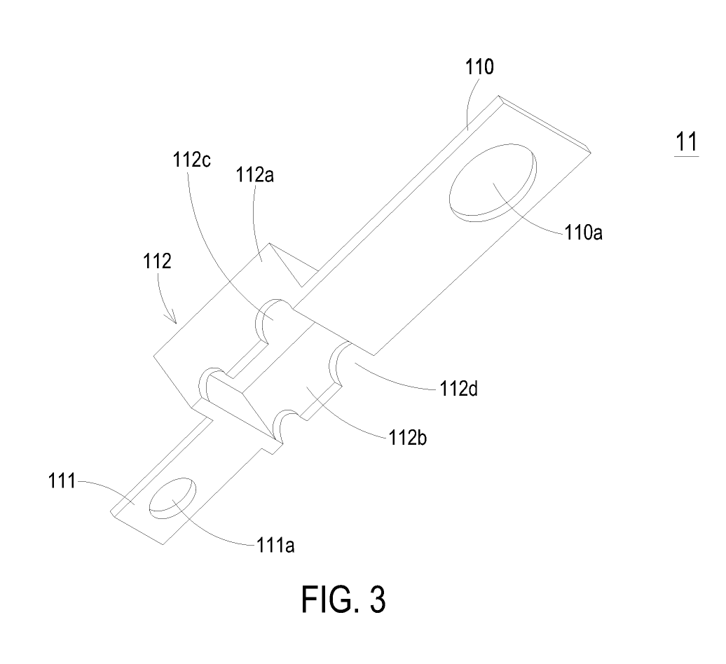

FIG. 3 is a schematic enlarged perspective view illustrating the clamping device as shown in FIG. 2. In this embodiment, the first end 110, the second end 111 and the pressing part 112 of the clamping device 11 are integrally formed. Moreover, the first end 110 and the second end 111 are extended from two opposed sides of the bottom of the pressing part 112, respectively.

In some embodiments, the pressing part 112 of the clamping device 11 comprises a first lateral plate 112a and a second lateral plate 112b. The first lateral plate 112a and the second lateral plate 112b are extended downwardly from two opposite sides of the top of the pressing part 112. In addition, the first lateral plate 112a and the second lateral plate 112b are parallel with each other. Moreover, a first notch 112c is located at a bottom of the first lateral plate 112a, and a second notch 112d is located at a bottom of the second lateral plate 112b. The first notch 112c and the second notch 112d are aligned with each other. Moreover, the sizes of the first notch 112c and the second notch 112d match the diameter of the ground wire 12. After the ground wire 12 is placed within the pressing part 112 and the casing 101, the ground wire 12 is at least partially accommodated within and clamped by the first notch 112c and the second notch 112d (see FIG. 1). Consequently, the ground wire 12 is fixed on the casing 101.

Moreover, in some embodiments, the first lateral plate 112a and the second lateral plate 112b comprise plural first notches 112c and plural second notches 112d, respectively, in order to accommodate the ground wires 12 with different diameters. For example, as shown in FIG. 3, the first lateral plate 112a and the second lateral plate 112b comprise two first notches 112c and two second notches 112d, respectively. Since the first notches 112c have different sizes and the second notches 112d have different sizes, the ground wire 12 with a specified diameter can be accommodated within the first notch 112c and the second notch 112d with the corresponding size.

In some embodiments, the second end 111 of the clamping device 11 further comprises a second opening 111a, and the second part B of the casing 101 has a second perforation 101b corresponding to the second opening 111a. In some embodiments, the assembling structure 1 further comprises a second fixing element 14 (e.g. a screw). By tightening the second fixing element 14 into the second opening 111a of the clamping device 11 and the second perforation 101b of the casing 101, the first end 110 of the clamping device 11 is fixed on the casing 101. In other words, the second end 111 of the clamping device 11 may be previously fixed on the second part B of the casing 101 by a machining process in a factory. In some other embodiments, the second fixing element 14 is a rivet. By penetrating the rivet through the second opening 111a of the clamping device 11 and the second perforation 101b of the casing 101, the second end 111 of the clamping device 11 may be previously fixed on the second part B of the casing 101.

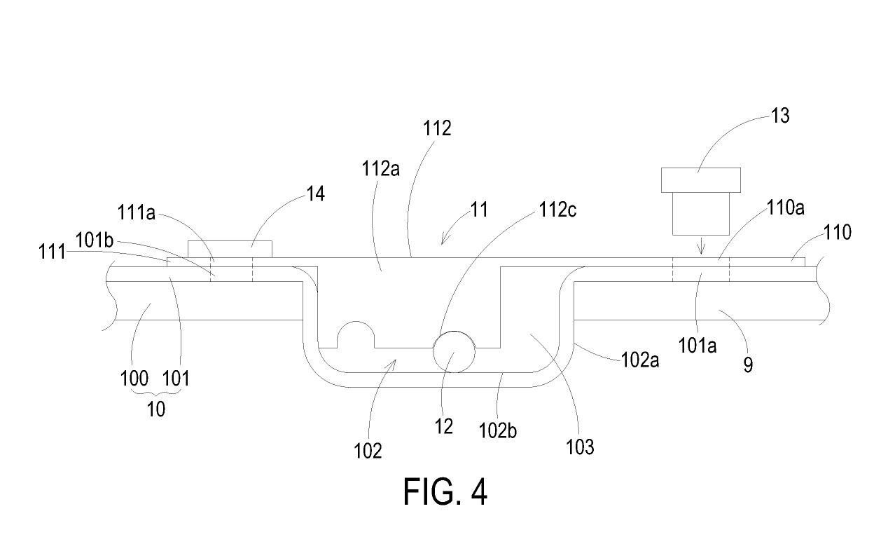

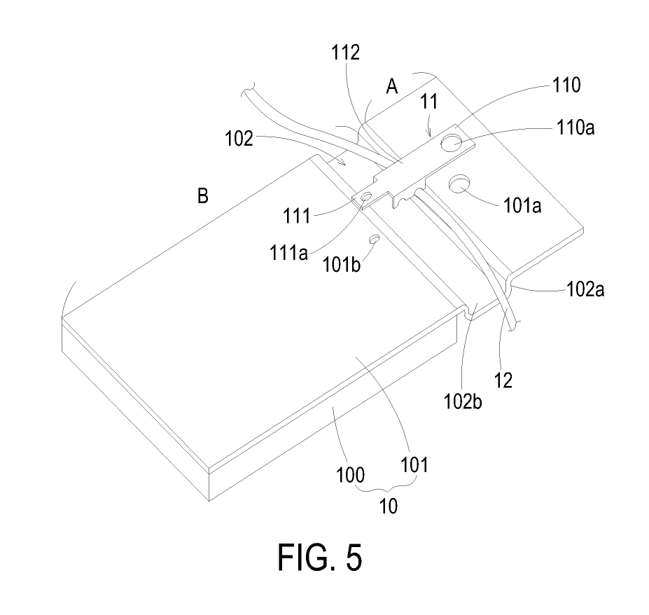

FIG. 4 is a schematic cross-sectional view illustrating an assembling structure fixed on a rack according to another embodiment of the present invention. FIG. 5 is a schematic perspective view illustrating a portion of the assembling structure of FIG. 4. The elements corresponding to those in FIG. 1 will be designated by identical numeral references. In comparison with the assembling structure of FIG. 1, the casing 101 of the inverter 10 of the assembling structure 1 as shown in FIGS. 4 and 5 further comprises a U-shaped recess 102. The U-shaped recess 102 is located at the second part B of the casing 101. Moreover, the U-shaped recess 102 is protruded from a bottom surface of the casing 101. In a case that the inverter 10 is fixed on the rack 9, an outer wall 102a of the U-shaped recess 102 is partially contacted with the rack 9 in order to provide a positioning function.

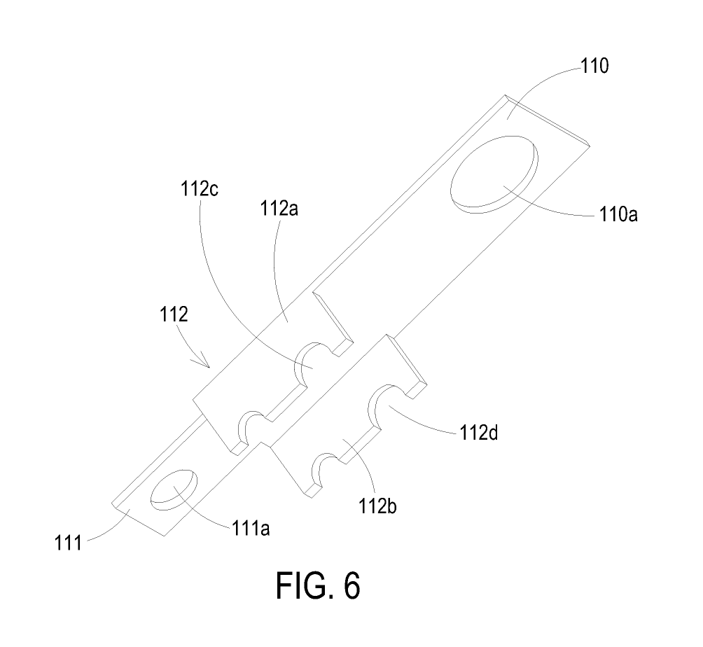

FIG. 6 is a schematic enlarged perspective view illustrating the clamping device as shown in FIG. 5. Please refer to FIGS. 4, 5 and 6. In this embodiment, the first end 110 and the second end 111 of the clamping device 11 are extended from two opposed sides of a top of the pressing part 112, respectively. The first lateral plate 112a and the second lateral plate 112b are extended downwardly from the top of the pressing part 112. In addition, the first lateral plate 112a and the second lateral plate 112b are parallel with each other. After the first end 110 and the second end 111 of the clamping device 11 are fixed on the casing 101, the pressing part 112 is accommodated within the U-shaped recess 102 in order to reduce the occupied space of the clamping device 11. Moreover, after the ground wire 12 may be introduced into the U-shaped recess 102 through an entrance between the first end 110 and the casing 101, the ground wire 12 is clamped between the pressing part 112 of the clamping device 11 and an inner surface 102b of the U-shaped recess 102.

Moreover, the U-shaped recess 102 is larger than the pressing part 112 of the clamping device 11. After the pressing part 112 is accommodated within the U-shaped recess 102, a receiving space 103 is defined by the first end 110 of the clamping device 11, the pressing part 112 of the clamping device 11 and the inner surface 102b of the U-shaped recess 102. Moreover, the width of the receiving space 103 is slightly larger than the diameter of the ground wire 12, so that the ground wire 12 is allowed to go through the receiving space 103. The ground wire 12 may be introduced into the region between the pressing part 112 and the inner surface 102b of the U-shaped recess 102 through the entrance between the first end 110 and the casing 101 and the receiving space 103. Consequently, the ground wire 12 is partially accommodated within the first notch 112c and the second notch 112d (see FIG. 4) or completely accommodated within the first notch 112c and the second notch 112d (not shown). Due to the receiving space 103 and the U-shaped recess 102, the ground wire 12 can be easily transferred through the entrance between the first end 110 and the casing 101 by slightly moving up the first end 110 of the clamping device 11. Under this circumstance, the possibility of causing damage of the clamping device 11 is minimized.

From the above descriptions, the present invention provides an assembling structure of an inverter and a ground wire. The assembling structure comprises a clamping device. A second end of the clamping device is previously fixed on a casing of the inverter, so that clamping device has the function of a resilient sheet. The ground wire is firstly clamped between the clamping device and the casing. Then, by manually tightening a first fixing element into a first opening of the clamping device and a first perforation of the casing, the ground wire and the inverter are simultaneously fixed. Consequently, it is not necessary to manually perform two fixing steps to position the ground wire and the inverter. In other words, the method of fixing the ground wire and the inverter according to the present invention is time-saving and labor-saving.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An assembling structure, comprising:
a ground wire;
an inverter comprising a casing, wherein said casing has a first perforation;
a first fixing element; and
a clamping device disposed on the casing, wherein said clamping device comprises a first end, a second end, and a pressing part between said first end and said second end, wherein said second end of said clamping device is previously fixed on said casing, and said first end of said clamping device has a first opening, wherein after said ground wire is transferred through an entrance between said first end of said clamping device and said casing, said ground wire is clamped between said pressing part and said casing, wherein after said first fixing element is tightened into said first opening and said first perforation, said first end of said clamping device is fixed on said casing, said ground wire is fixed on said casing by said pressing part of said clamping device, and said inverter is fixed on a rack simultaneously.

2. The assembling structure according to claim 1, wherein said first end, said second end and said pressing part of said clamping device are integrally formed.

3. The assembling structure according to claim 1, wherein said first end and said second end are extended from two opposed sides of a bottom of said pressing part, respectively.

4. The assembling structure according to claim 1, wherein said casing further comprises a U-shaped recess, wherein said U-shaped recess is protruded from a bottom surface of said casing, and an outer wall of said U-shaped recess is partially contacted with said rack.

5. The assembling structure according to claim 4, wherein said pressing part of said clamping device is accommodated within said U-shaped recess, and said ground wire is clamped between said pressing part and an inner surface of said U-shaped recess.

6. The assembling structure according to claim 5, wherein after said pressing part of said clamping device is accommodated within said U-shaped recess, a receiving space is defined by said first end of said clamping device, said pressing part and said inner surface of said U-shaped recess, wherein said ground wire is introduced into a region between said pressing part and said inner surface of said U-shaped recess through said entrance and said receiving space.

7. The assembling structure according to claim 6, wherein a width of said receiving space is slightly larger than a diameter of said ground wire.

8. The assembling structure according to claim 5, wherein said first end and said second end are extended from two opposed sides of a top of said pressing part, respectively.

9. The assembling structure according to claim 1, wherein said pressing part of said clamping device comprises a first lateral plate and a second lateral plate, wherein said first lateral plate and said second lateral plate are extended downwardly from two opposite sides of a top of said pressing part, and said first lateral plate and said second lateral plate are parallel with each other.

10. The assembling structure according to claim 9, wherein said first lateral plate comprises at least one first notch, and said second lateral plate comprises at least one second notch, wherein a width of said first notch and a width of said second notch match a diameter of said ground wire, so that said ground wire is at least partially accommodated within said first notch and said second notch.

11. The assembling structure according to claim 1, wherein said second end of said clamping device further comprises a second opening, and said casing further comprises a second perforation corresponding to said second opening

12. The assembling structure according to claim 11, further comprising a second fixing element, wherein after said second fixing element is tightened into said second opening and said second perforation, said second end of said clamping device is previously fixed on said casing.

13. The assembling structure according to claim 1, wherein after said first fixing element is tightened into said first opening, said first perforation and a corresponding hole of said rack, said first end of said clamping device is fixed on said casing, said ground wire is fixed on said casing by said pressing part of said clamping device, and said inverter is fixed on said rack simultaneously.
